(19) United States
(12) Patent Application Publication
(10) Pub. No.: US 2010/0326488 A1
(43) Pub. Date: Dec. 30, 2010

(54) Simulated photovoltaic module and array including same

(76) Inventors: Robert Aue, East Rockaway, NY (US); Hector Mascaros, Greenlawn, NY (US)

Correspondence Address: COLLARD & ROE, P.C., 1077 NORTHERN BOULEVARD, ROSLYN, NY, 11576, US

(21) Appl. No.: 12/459,170

(22) Filed: Jun. 26, 2009

(51) Int. Cl. H01L 31/042

(52) U.S. Cl. 136/244

(57) ABSTRACT

A photovoltaic array includes a functioning photovoltaic module for converting sunlight into electricity. The functioning photovoltaic module includes a first panel having a first exterior surface. The array further includes a simulated photovoltaic module disposed adjacent to the functioning photovoltaic module. The simulated photovoltaic module includes a second panel having a second exterior surface simulating an appearance of the first exterior surface of the functioning photovoltaic module.

### BACKGROUND OF THE INVENTION

1. Field of the Invention

The invention relates to photovoltaic arrays. In particular, the invention relates to a photovoltaic array and a method for providing such an array including a simulated photovoltaic module having the appearance of a functioning photovoltaic module.

2. The Prior Art

Photovoltaic modules are installed on various surfaces, such as, for example, a rooftop, for converting sunlight into electricity. Large gaps are often left in an array of photovoltaic modules for a number of reasons. These reasons include the presence of obstacles, such as for example, chimneys or vent pipes. Gaps are also typically left in an array of photovoltaic modules in areas that are continually or predominantly shaded, for example, by trees, shrubs, chimneys, vent pipes, satellite dishes, antennae, electric lines, air conditioning units or adjacent roofs, because of the low efficiency associated with such shaded areas. Moreover, gaps in the array may be left at angled junctions between two adjoining roof portions.

Gaps in the array of photovoltaic modules result in an asymmetric arrangement that is not visually appealing. However, existing functional photovoltaic modules with associated electrical components cannot be machined to accommodate obstacles or irregular geometries without damaging the module.

Moreover, manufacturing functioning photovoltaic modules with multiple or irregular shapes or angles is cost prohibitive. For example, the commercially available Sharp® ND-72ERUF is a triangular shaped panel having an angle of about 45 degrees. This panel is typically used to follow the contour of the valley between two adjoining roof sections. However, due to the expense of manufacturing functioning photovoltaic modules, very few angled panels are available.

Accordingly, a need exists for an inexpensive simulated photovoltaic module which simulates the appearance of a functioning photovoltaic module. Moreover, a need exists for a simulated photovoltaic module which can be readily shaped or machined to accommodate various geometries and/or obstacles. A need further exists for a simulated photovoltaic module which can be incorporated into an array of functioning photovoltaic modules to eliminate gaps in the array and to provide a pleasing, aesthetic appearance.

### SUMMARY OF THE INVENTION

The invention relates to photovoltaic arrays. In particular, the invention relates to a photovoltaic array and a method for providing such an array including a simulated photovoltaic module having the appearance of a functioning photovoltaic module.

A photovoltaic array according to an aspect of the invention includes a functioning photovoltaic module for converting sunlight into electricity. The functioning photovoltaic module includes a first panel having a first exterior surface. The photovoltaic array further includes a simulated photovoltaic module disposed adjacent to the functioning photovoltaic module. The simulated photovoltaic module includes a second panel having a second exterior surface simulating an appearance of the first exterior surface of the functioning photovoltaic module.

A simulated photovoltaic module for a photovoltaic array according to an aspect of the invention includes a panel having an exterior surface simulating an appearance of an exterior surface of a functioning photovoltaic module.

A method for providing a photovoltaic array according to an aspect of the invention includes the steps of securing a functioning photovoltaic module for converting sunlight into electricity onto a surface. The functioning photovoltaic module includes a first panel having a first exterior surface. The method further includes the step of securing a simulated photovoltaic module onto the surface adjacent to the functioning photovoltaic module. The simulated photovoltaic module includes a second panel having a second exterior surface simulating an appearance of the first exterior surface of the functioning photovoltaic module.

An advantage of a photovoltaic array including a simulated photovoltaic module and a method for providing same according to an aspect of the invention is that an inexpensive, non-functioning simulated photovoltaic module is provided which simulates the appearance of a functioning photovoltaic module. The simulated photovoltaic module can be incorporated into an array of functioning photovoltaic modules to eliminate gaps, thereby creating an aesthetically pleasing and/or symmetric design. By using a simulated photovoltaic module, the manufacture of many different angles would be much less costly and moreover, the simulated modules could be customized on site as needed, for example, to match the roof valley pitches.

A further advantage of a photovoltaic array including a simulated photovoltaic module and a method for providing same according to an aspect of the invention is that a simulated photovoltaic module is provided which can be readily machined, formed or otherwise shaped to accommodate various geometries and/or obstacles encountered in an installation.

Another advantage of a photovoltaic array including a simulated photovoltaic module and a method for providing same according to an aspect of the invention is that the simulated photovoltaic module may be arranged in a shaded portion of the mounting surface without detracting from the efficiency of the array.

Another advantage of a photovoltaic array including a simulated photovoltaic module and a method for providing same according to an aspect of the invention is that the simulated photovoltaic module may be constructed to be capable of supporting a person and may further incorporate handholds, footholds and/or climbing cleats to facilitate access to the array.

Another advantage of a photovoltaic array including a simulated photovoltaic module and a method for providing same according to an aspect of the invention is that the simulated photovoltaic module may be hinged or include a hinged portion for providing access to an area under the panel.

### BRIEF DESCRIPTION OF THE DRAWINGS

Other benefits and features of the present invention will become apparent from the following detailed description considered in connection with the accompanying drawings. It is to be understood, however, that the drawings are designed as an illustration only and not as a definition of the limits of the invention.

In the drawings, wherein similar reference characters denote similar elements throughout the several views:

FIG. 1A shows a roof-mounted array of functioning photovoltaic modules having a gap in the array due to an obstacle;

FIG. 1B shows a roof-mounted array of functioning photovoltaic modules including a simulated photovoltaic module with an opening to accommodate the obstacle;

FIG. 2A shows a roof-mounted array of functioning photovoltaic modules having a gap in the array due to the roof geometry;

FIG. 2B shows a roof-mounted array of functioning photovoltaic modules including simulated photovoltaic modules shaped to accommodate the roof geometry;

FIG. 3A shows a roof-mounted array of functioning photovoltaic modules having a gap in the array at a shaded portion of the roof;

FIG. 3B shows a roof-mounted array of functioning photovoltaic modules including simulated photovoltaic modules mounted at the shaded portion of the roof;

FIG. 4A shows a top view of a simulated photovoltaic module according to an aspect of the invention;

FIG. 4B shows an end view of the simulated photovoltaic module of FIG. 4A;

FIG. 4C shows a side view of the simulated photovoltaic module of FIG. 4A;

FIG. 4D shows an end view of the simulated photovoltaic module of FIG. 4A having an end cover;

FIG. 5A shows a top view of a simulated photovoltaic module having a hinged portion according to an aspect of the invention;

FIG. 5B shows an end view of a simulated photovoltaic module having a hinged portion according to an aspect of the invention;

FIG. 6 shows a section along line 6-6 in FIG. 5a;

FIG. 7A shows a top view of a simulated photovoltaic module according to an aspect of the invention;

FIG. 7B shows an end view of the simulated photovoltaic module shown in FIG. 7A;

FIG. 8A shows a top view of a simulated photovoltaic module according to an aspect of the invention;

FIG. 8B shows a sectional view of the simulated photovoltaic module shown in FIG. 8A;

FIG. 8C shows a side view of the simulated photovoltaic module shown in FIG. 8A;

FIG. 8D shows an end view of the simulated photovoltaic module shown in FIG. 8A

FIG. 9 shows a top view of a simulated photovoltaic module having an opening to accommodate an obstacle according to an aspect of the invention;

FIG. 10 shows a section along line 10-10 in FIG. 9;

FIG. 11 shows a top view of a simulated photovoltaic module having openings for handholds and/or footholds according to an aspect of the invention;

FIG. 12 shows a section along line 12-12 in FIG. 11 with the simulated photovoltaic module installed on a roof;

FIG. 13 shows a section along line 13-13 in FIG. 11 with a slip-in climbing cleat disposed in an opening in the simulated photovoltaic module;

FIG. 14A shows a top view of a simulated photovoltaic module with climbing cleats secured thereto according to an aspect of the invention;

FIG. 14B shows side view thereof; and

FIG. 14C shows a bottom edge view thereof.

### DETAILED DESCRIPTION OF THE DRAWINGS

The present invention relates to the overall appearance of a photovoltaic array. The photovoltaic array may be mounted to a roof, a wall, the ground or other mounting surfaces. As a result of obstacles, inefficiencies due to shading and various mounting surface geometries, a continuous symmetrical array of functioning photovoltaic modules or panels may be infeasible or impossible. The overall appearance of an array with missing modules is not as appealing to the eye as a complete or nearly complete, symmetrical array covering all or substantially all of the mounting surface.

Obstacles, such as chimneys, vent pipes, satellite dishes, antennas, and the like generally cannot be moved to other locations. As existing functioning photovoltaic modules cannot be cut, drilled, or otherwise machined to accommodate such obstacles without damaging the module, the obstacle requires the elimination of a functioning photovoltaic module in the array, causing a gap and/or an asymmetric array.

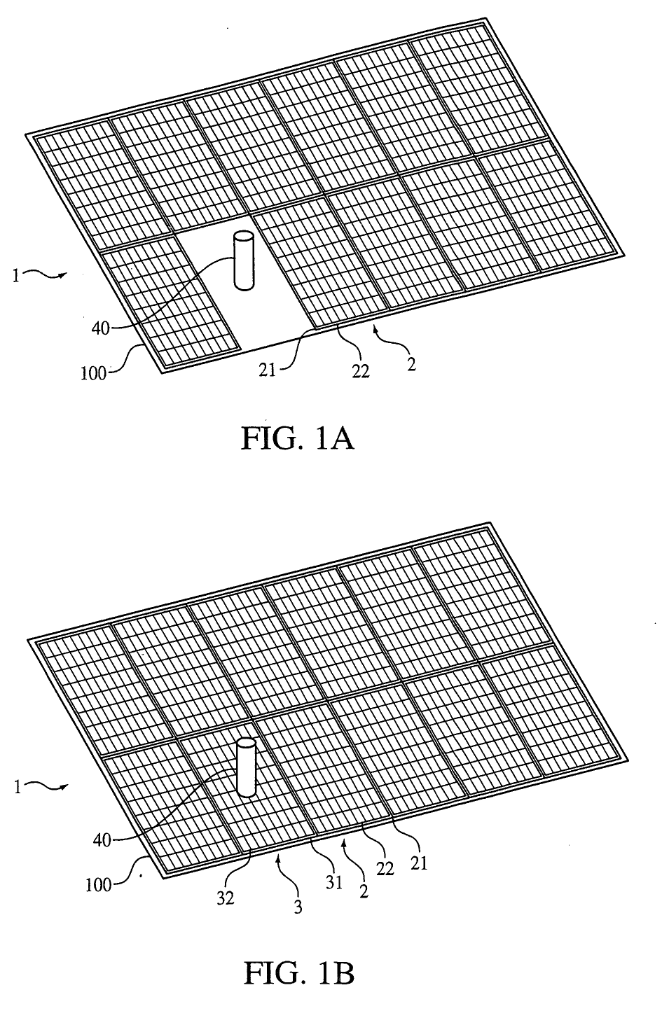

For example, FIG. 1A shows a roof-mounted photovoltaic array 1 including functioning photovoltaic modules 2 mounted to a roof surface 100 for converting sunlight into electricity. Each of functioning photovoltaic modules 2 include a first panel 21 having a first exterior surface 22. An obstacle 40, for example, a vent pipe, projects upwardly form the roof surface 100. As shown in FIG. 1A, a functioning photovoltaic module 2 cannot be located in the area proximate to the obstacle 40, causing a gap in the array and detracting from its overall aesthetic appearance.

FIG. 1B shows a roof-mounted photovoltaic array similar to the one shown in FIG. 1A, and further including a simulated photovoltaic module 3 disposed adjacent to one or more of the functioning photovoltaic modules 2. Simulated photovoltaic module 3 includes a second panel 31 having a second exterior surface 32 which simulates the appearance of the exterior surface 22 of the functioning photovoltaic modules 2.

As shown in detail in FIG. 10, panel 31 of the simulated photovoltaic module 3 includes an opening 33. Opening 33 is sized and located to allow obstacle 40 projecting upwardly from roof 100 to pass through the panel 31, thereby allowing the simulated panel 3 to be positioned adjacent to the obstacle 40 and eliminating the gap in the array 1.

The simulated photovoltaic module 3 would generally comprise a non-functioning look-alike module. This simulated module should have the same or a substantially similar appearance to the particular functioning photovoltaic module used in the array. Simulated photovoltaic modules 3 could be made to have the same or a similar shape, dimensions, color and/or appearance as functioning photovoltaic modules now available or developed in the future.

Simulated photovoltaic modules 3 would differ from functioning photovoltaic modules in a number of ways. In particular, the simulated photovoltaic modules 3 would not include the electrical components of the functioning modules necessary to produce electricity. Additionally, it is contemplated that the simulated photovoltaic modules 3 would be significantly lower in cost than a functioning photovoltaic module.

Moreover, as set forth herein, the simulated photovoltaic modules 3 could be cut, drilled, notched, machined, or otherwise shaped. For example, the simulated module could be cut and positioned over an obstacle, such as a vent pipe or notched to butt up against a chimney, thereby eliminating the gap in an array which would otherwise be required. Moreover, the simulated photovoltaic module 3 could be used to hide a junction box, and could be removed to gain access to a junction box for testing and troubleshooting without having to disconnect electrical components. The panel 31 of the simulated photovoltaic module 3 or a portion thereof, may be hinged to provide easy access to an area below the panel. A junction box could also be incorporated into the simulated photovoltaic module 3 to provide access to the junction box from the top.

Permits for solar arrays in some communities requires the submission of architectural drawings showing the appearance of the installed system. The use of simulated photovoltaic modules 3 according to an aspect of the invention would improve the appearance of the installed array and may facilitate approval of the required permit.

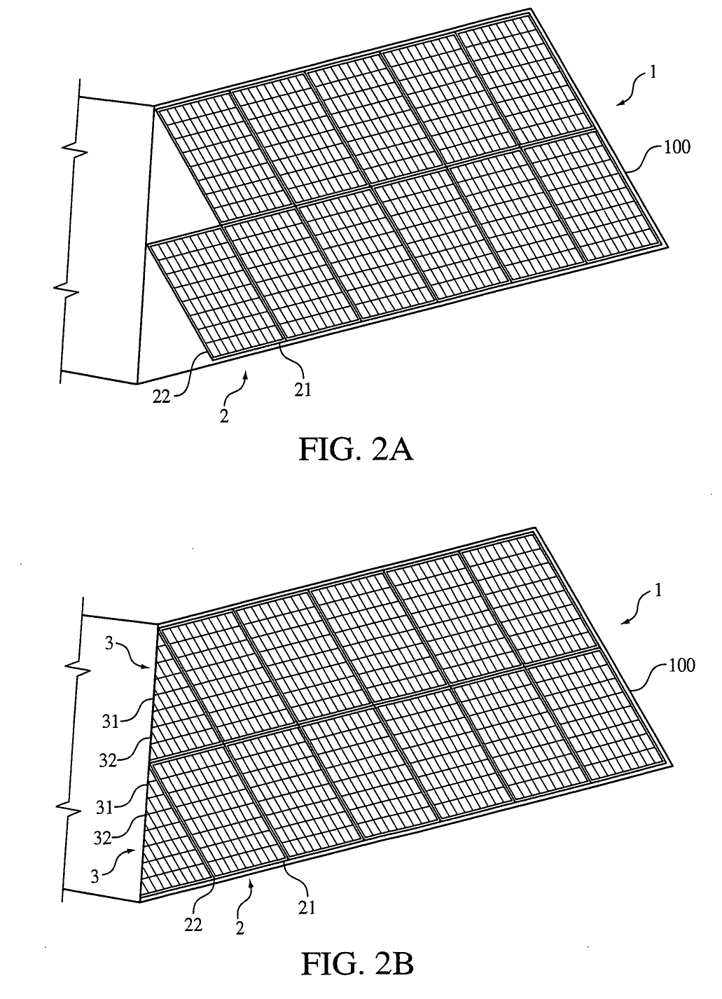

FIG. 2A shows a roof-mounted array 1 of functioning photovoltaic modules 2 having a gap in the array due to the roof geometry. FIG. 2B shows a roof-mounted array 3 of functioning photovoltaic modules 2 including simulated photovoltaic modules 3 shaped to accommodate the roof geometry. Simulated photovoltaic modules 3 have been cut or machined to conform to the roof edge and simulate the appearance of the functioning modules 2, thereby giving the array 1 a more pleasing appearance.

Even partial shading causes a total decrease in the overall efficiency of the photovoltaic array. Shading may be caused by various features, such as trees, shrubs, chimneys, vent pipes, satellite dishes, electric lines, antennas, air conditioning units, and/or adjacent roofs. Due to the low efficiency associated with the shaded areas, photovoltaic modules are typically not installed in the shaded areas and a gap in the array results. If cutting or machining of the module is not required, actual photovoltaic modules could be installed at the shaded area without electrically connecting the functioning photovoltaic modules. This arrangement would not reduce the efficiency of the array. This solution, however, is a very expensive way to maintain the symmetry of the array. The use of a simulated photovoltaic module 3 according to an aspect of the invention would provide a much more cost effective way of improving the appearance of the array.

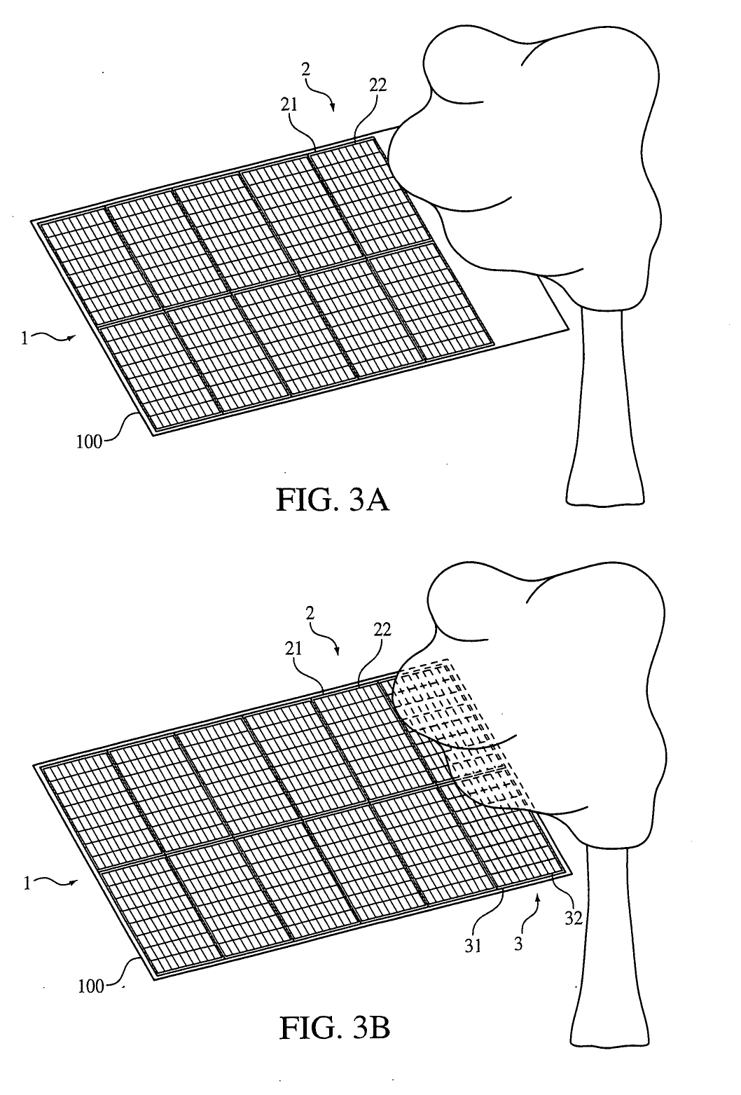

For example, FIG. 3A shows a roof 100 having a portion shaded by a tree. A roof-mounted array 1 of functioning photovoltaic modules 2 includes a gap in the array 1 at the shaded portion of the roof. FIG. 3B shows a roof-mounted array of functioning photovoltaic modules including simulated photovoltaic modules 3 mounted at the shaded portion of the roof;

The components and materials used to construct a simulated photovoltaic module 3 may include a frame formed from aluminum, stainless steel, or any other weather resistant metal or plastic material. The selected material and design would provide a structurally sound frame. Preferably, the frame of the simulated photovoltaic module would have the same appearance and color as the frame of an adjacent functioning photovoltaic module 2. For example, the simulated module's frame could be painted, powder coated, anodized, or extruded to produce an appearance mimicking that of the functioning photovoltaic modules being used in the particular array.

The frame and panel 31 of a simulated photovoltaic module 3 may be permanently or removably fastened together, for example, by welding, gluing, riveting, or bolting. The frame and panel may be separated for drilling, notching, or other operations.

A panel 31 of the simulated photovoltaic module 3 may be made from various materials or combinations of materials, for example, plastic, fiberglass, wood, metal, glass, and/or laminate. The panel 31 of the simulated photovoltaic module 3 would have the same or a substantially similar appearance as the panels 21 of the functioning photovoltaic modules 2 in the array 1. In particular, the exterior surface 32 of panel 31 would have the same or a substantially similar appearance as the exterior surface 22 of a panel 21 of the functioning photovoltaic module 2. This appearance may include color, design, texture, and any other features which would make the simulated photovoltaic module 3 closely resemble the functioning photovoltaic modules 2 in an array 1.

The appearance of the simulated photovoltaic module 3 may be achieved using various techniques, such as for example, painting, powder coating, silk screening, etching, laminating, applying decals, or a combination of printing and/or coloring techniques.

The materials used for constructing the simulated photovoltaic module 3 may include ultraviolet protection to prevent fading or decomposing of the module.

The simulated photovoltaic module 3 could be made to conform to standard shapes and sizes of functioning photovoltaic modules offered by manufacturers, but would not be limited to such standard shapes and sizes.

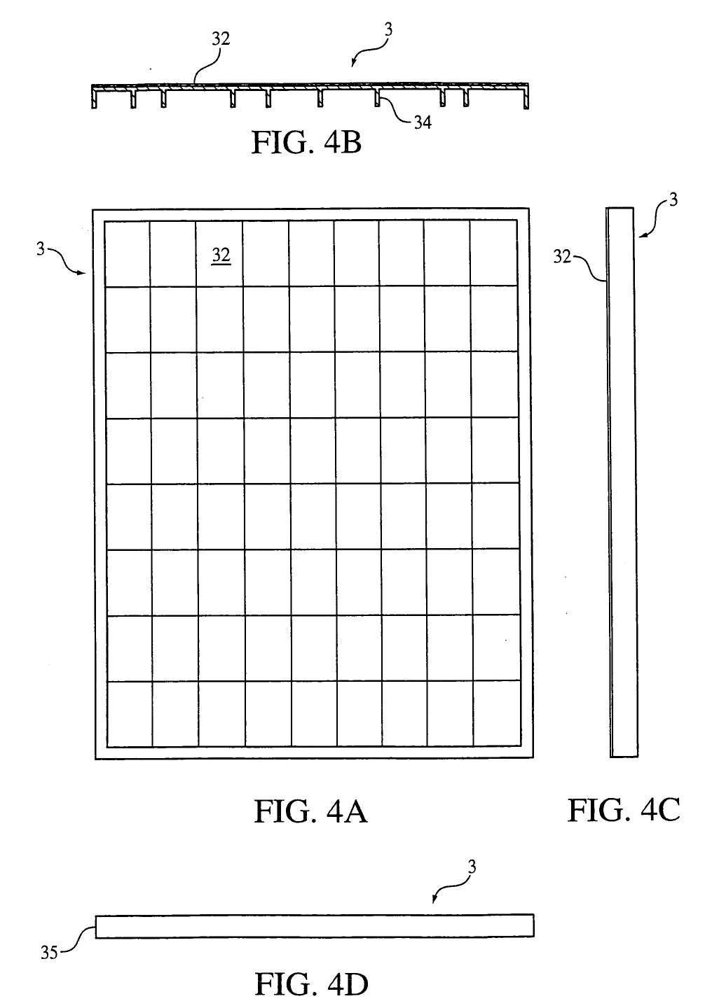

FIG. 4A shows a top view of a simulated photovoltaic module 3 according to an aspect of the invention and FIG. 4B shows an end view of the simulated photovoltaic module 3 of FIG. 4A. The simulated photovoltaic module may be made from an extruded plastic or other material. Reinforcing ribs 34 may be disposed on the underside of the module 3 to provide strength and/or to give the appearance of an outside frame. Ribs 34 may be located in such a way as to allow the simulated module 3 to be cut at the rib points, thereby permitting simulated modules having different widths to be made from a single extruded part.

The height (depth) of an extruded simulated photovoltaic module 3 can be made to correspond to the height (depth) of the functioning photovoltaic modules 2 in the associated array, or the extruded simulated photovoltaic module 3 could be planed or shimmed to match the height (depth) of the functioning photovoltaic modules 2 in the associated array.

The extruded simulated photovoltaic module 3 could be cut to length to match the functioning photovoltaic modules 2 in the associated array.

FIG. 4C shows a side view of the simulated photovoltaic module of FIG. 4A. As shown in FIG. 4D, an end of the extruded simulated photovoltaic module 3 could be covered with an optional end cover 35 which hides the reinforcing ribs 34. The end piece or cover 35 would be preferably used in installations where the end of the simulated photovoltaic module 3 could be seen from the ground. The same type of end cover 35 could be used if the simulated photovoltaic module 3 were notched or cut on an angle. End cover 35 may be fastened to the simulated photovoltaic module 3, for example, with screws or adhesive. The top surface (exterior surface 32) of simulated photovoltaic module 3 would be made to simulate the appearance of the exterior surface 22 of the functioning photovoltaic panel 2, for example, by painting, powder coating, silk screening, etching, laminating, applying decals, or a combination of printing and/or coloring techniques.

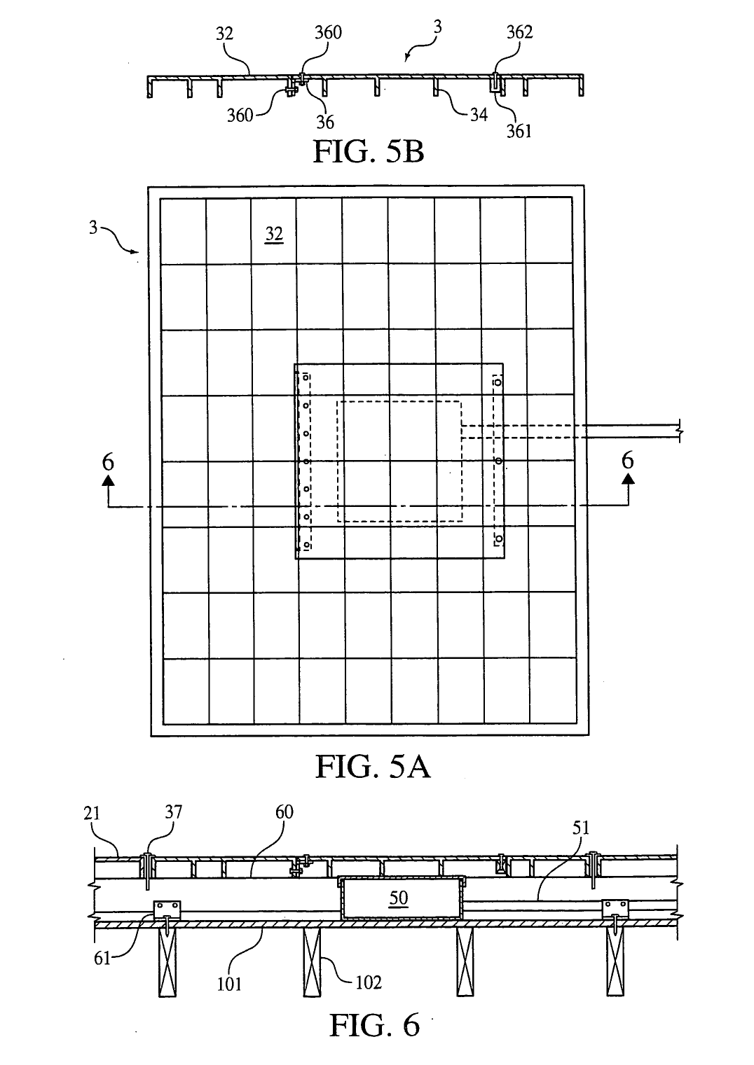

At least a portion of the simulated photovoltaic module panel 31 may be hinged for providing access to an area below the panel. For example, FIG. 5A shows a top view of a simulated photovoltaic module 3 having a hinged portion according to an aspect of the invention. FIG. 5B shows an end view of a simulated photovoltaic module 3 having a hinged portion according to an aspect of the invention and FIG. 6 shows a section along line 6-6 in FIG. 5a. The hinged portion or hatch may provide access to a junction box 50 coupled to conduit 51 or electrical wires for the array, inverter, or other electric component of the system. As shown in FIG. 5B, a hinge 36 is coupled to the hinged portion of the simulated module panel. The hinge 36 may be secured with one or more hinge fastener 360 and a block 361 may be provided to act as a hinged panel door stop. A locking mechanism 362 may be incorporated for securing the hinged portion in a closed position.

Panel fasteners 37 may be used to secure the simulated photovoltaic module 3 to a mounting rail 60. This mounting rail 60 is secured to the roof with roof anchors 61, which, as shown in FIG. 6, may extend through the roof sheathing 101 and into the roof rafters 102.

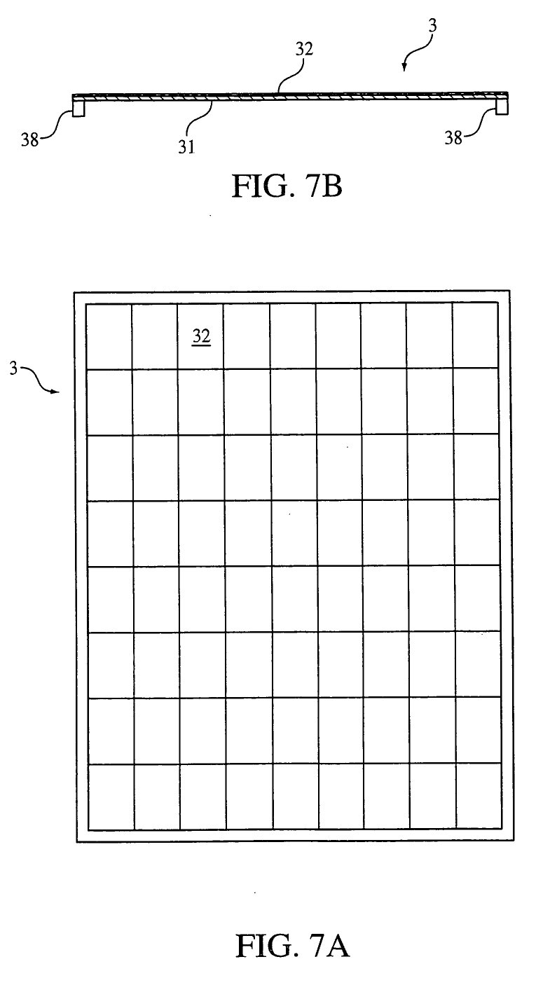

The simulated photovoltaic module 3 may also be constructed with a stiff panel material, for example, plastic, wood, polycarbonate, fiberglass, metal, or the like. FIG. 7A shows a top view of a simulated photovoltaic module 3 according to this aspect of the invention and FIG. 7B shows an end view of the simulated photovoltaic module 3 shown in FIG. 7A. As shown, blocking or shims 38 are attached under the simulated photovoltaic module 3 where it attaches to a mounting rail in order to maintain the desired height of the simulated photovoltaic module 3. The top surface (exterior surface 32) of simulated photovoltaic module 3 would be made to simulate the appearance of the exterior surface 22 of the functioning photovoltaic panel 2, for example, by painting, powder coating, silk screening, etching, laminating, applying decals, or a combination of printing and/or coloring techniques.

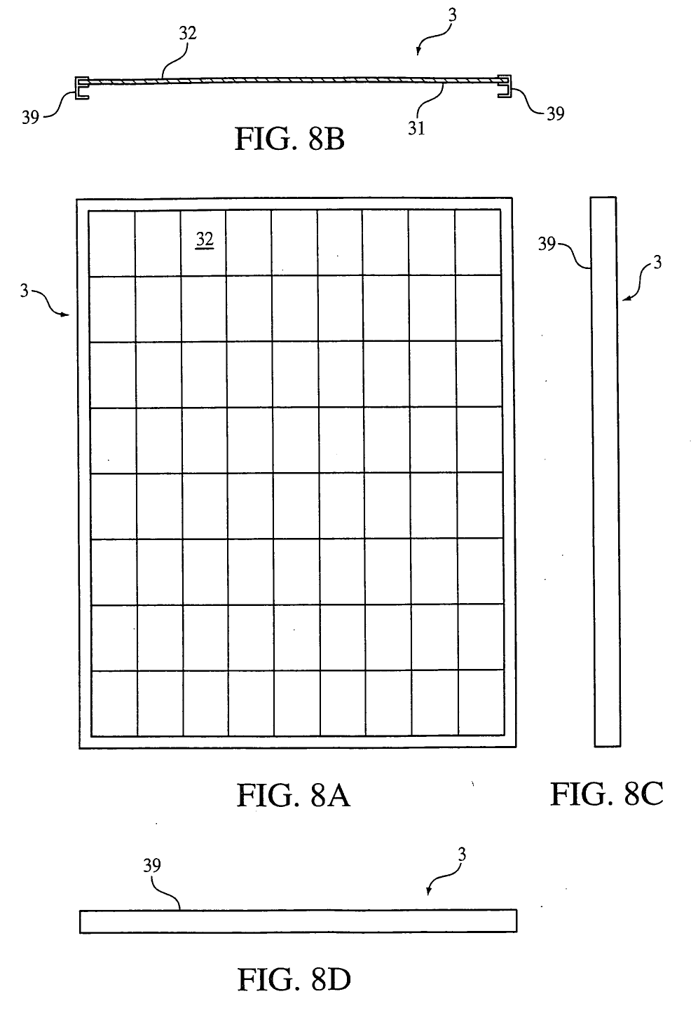

FIGS. 8A through 8D show a simulated photovoltaic module 3 including a frame 39 which may extend around a perimeter of the module. The simulated photovoltaic module 3 includes an insert panel 31 supported by the frame 39.

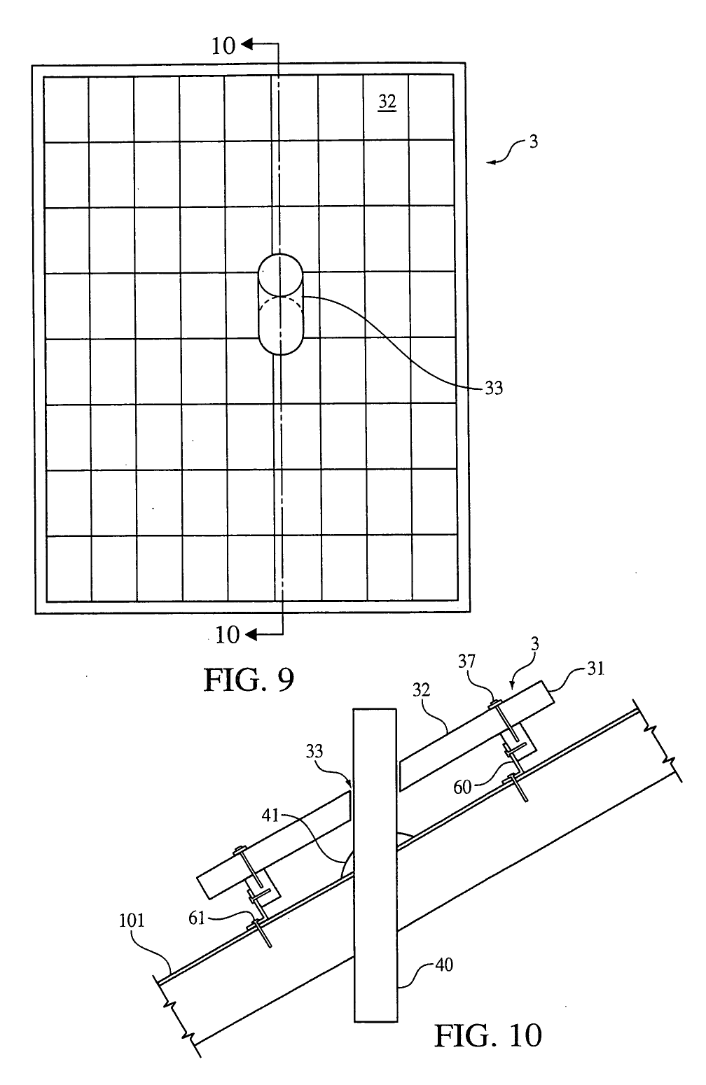

FIG. 9 shows a top view of a simulated photovoltaic module 3 having an opening 33 to accommodate an obstacle 40 and FIG. 10 shows a section along line 10-10 in FIG. 9. As shown, the obstacle 40 may be a vent pipe extending upwardly from a roof. Flashing 41 may be provided around the vent pipe at the roof sheathing 101. Opening 33 is sized and located to allow obstruction 40 to pass through the simulated photovoltaic module panel 31. The simulated photovoltaic module 3 may be secured to mounting rail 60 using panel fasteners 37. Mounting rail 60 may be secured to the roof using roof anchors 61.

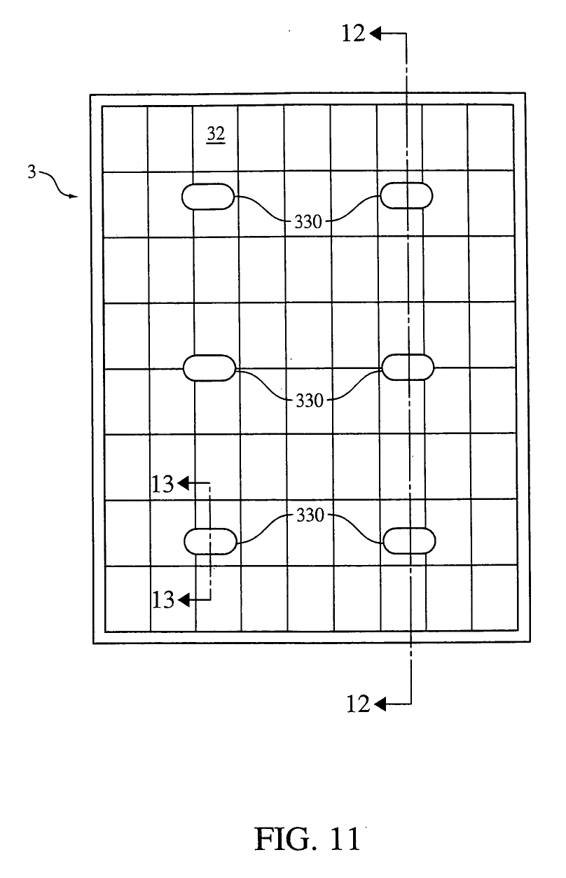

The simulated photovoltaic module 3 may be constructed to be able to support a person's weight when the simulated module is installed in the array. Such a simulated photovoltaic module may include openings 330, as shown in FIG. 11. The openings 330 are arranged and dimensioned to serve as handholds and/or footholds to facilitate a person gaining access to the roof or other parts of the array for testing, maintenance, or repair.

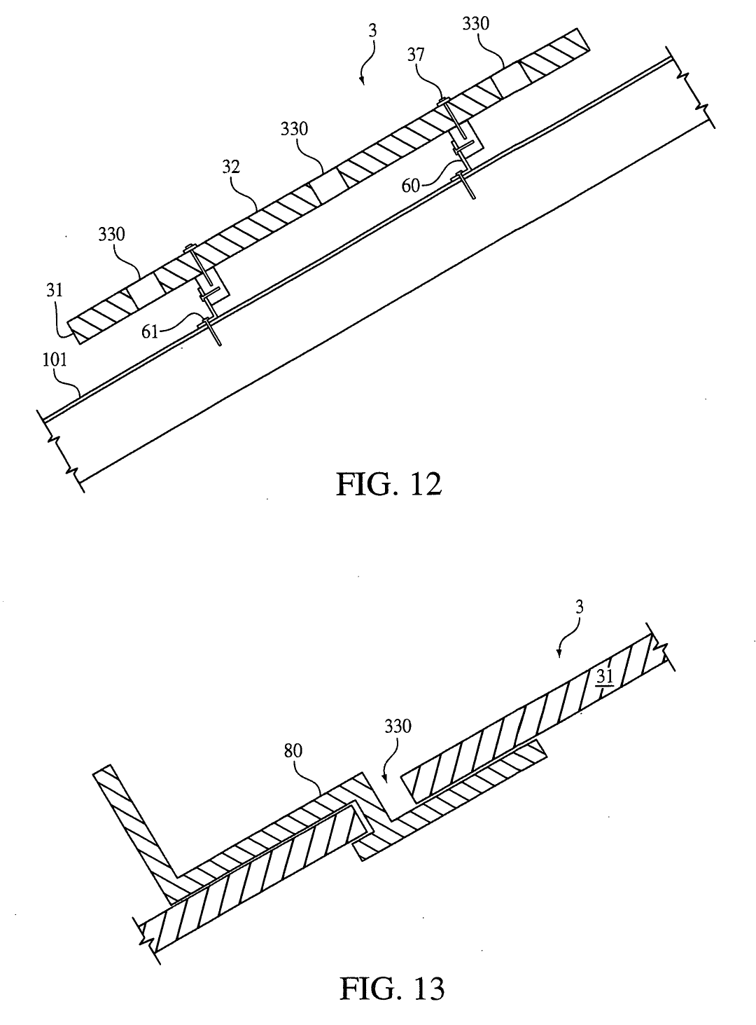

FIG. 12 shows a section along line 12-12 in FIG. 11 with the simulated photovoltaic module 3 having handhold or foothold openings 330 installed on a roof. As shown for example in FIG. 13, which shows a section along line 13-13 in FIG. 11, the openings 330 may also be used to support a slip-in climbing cleat 80. Slip in climbing cleat 80 may also be fitted to an attachment point on the simulated photovoltaic module panel 31 or in a slot provided therethrough. The slip in climbing cleat 80 is removable and accordingly could be removed when not in use; so that, it is not visible from the ground.

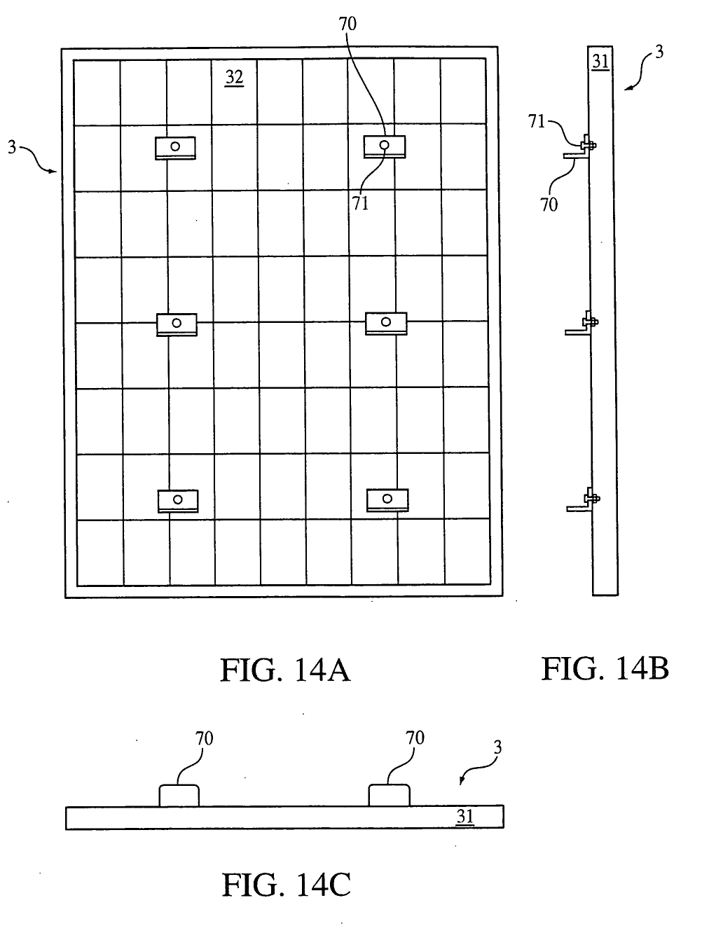

FIGS. 14A-14C shows a simulated photovoltaic module 3 having climbing cleats 70 secured thereto. Climbing cleats 70 may be secured to the simulated photovoltaic module 3 with fastener 71 and may be permanently secured or removable. Additionally, the handhold/foothold openings 330, the slip-in cleat 80 and/or the climbing cleats 70 may be factory installed or installed at the job site.

For applications including multiple string arrays of functioning photovoltaic modules 2, additional simulated photovoltaic modules 3 may be used to keep the strings in equal voltages. In this application, the simulated photovoltaic module may be narrower reducing the space occupied by the simulated photovoltaic module. Additionally, the climbing features, described above, would be particularly useful in a multiple string array.

Although several embodiments of the present invention have been shown and described, it is obvious that many changes and modifications may be made thereunto without departing from the spirit and scope of the invention.

What is claimed is:

1. A photovoltaic array comprising:
a) a functioning photovoltaic module for converting sunlight into electricity, said functioning photovoltaic module comprising a first panel having a first exterior surface; and
b) a simulated photovoltaic module disposed adjacent to said functioning photovoltaic module, said simulated photovoltaic module comprising a second panel having a second exterior surface simulating an appearance of said first exterior surface of said functioning photovoltaic module.

2. The photovoltaic array according to claim 1, wherein said second panel of said simulated photovoltaic module comprises an opening therethrough, said opening being sized and located to allow an obstacle projecting upwardly to pass through said second panel.

3. The photovoltaic array according to claim 1, wherein at least a portion of said second panel is hinged for providing access to an area below said second panel.

4. The photovoltaic array according to claim 1, wherein said simulated photovoltaic module is constructed so as to be capable of supporting a person when said simulated photovoltaic module is in an installed condition.

5. The photovoltaic array according to claim 4, wherein said second panel of said simulated photovoltaic module has a plurality of openings therethrough, said openings providing at least one of a foothold and a handhold.

6. A simulated photovoltaic module for a photovoltaic array, the simulated photovoltaic module comprising a panel having an exterior surface simulating an appearance of an exterior surface of a functioning photovoltaic module.

7. The simulated photovoltaic module according to claim 6, wherein said simulated photovoltaic module further comprises a frame to which said panel is secured.

8. The simulated photovoltaic module according to claim 6, further comprising an opening therethrough, said opening being sized and located to allow an obstacle projecting upwardly to pass through said panel.

9. The simulated photovoltaic module according to claim 6, wherein at least a portion of said panel is hinged for providing access to an area below said panel when said simulated photovoltaic module is installed in the array.

10. The simulated photovoltaic module according to claim 6, wherein said simulated photovoltaic module is constructed so as to be capable of supporting a person when said simulated photovoltaic module is installed in the array.

11. The simulated photovoltaic module according to claim 10, wherein said panel of said simulated photovoltaic module has a plurality of openings therethrough, said openings providing at least one of a foothold and a handhold.

12. The simulated photovoltaic module according to claim 10, further comprising a climbing cleat secured to said panel.

13. The simulated photovoltaic module according to claim 10, further comprising a removable slip-in climbing cleat adapted to be supported in an opening in said panel.

14. A method for providing a photovoltaic array, the method comprising the steps of:
a) securing a functioning photovoltaic module for converting sunlight into electricity onto a surface, said functioning photovoltaic module comprising a first panel having a first exterior surface; and
b) securing a simulated photovoltaic module onto the surface adjacent to said functioning photovoltaic module, said simulated photovoltaic module comprising a second panel having a second exterior surface simulating an appearance of said first exterior surface of said functioning photovoltaic module.

15. The method for providing a photovoltaic array according to claim 14, further comprising the step of shaping said second panel to conform to at least one of a roof and a roof structure.

16. The method for providing a photovoltaic array according to claim 14, further comprising the step of forming an opening through said second panel, said opening being sized and located to allow an obstacle projecting upwardly to pass through said second panel.

17. The method for providing a photovoltaic array according to claim 14, further comprising the step of securing at least a portion of said second panel with a hinge for providing access to an area below said second panel when said simulated photovoltaic module is in an installed condition.

18. The method for providing a photovoltaic array according to claim 14, further comprising the step of forming at least one of a foothold and a handhold in said second panel.

19. The method for providing a photovoltaic array according to claim 14, further comprising the step of securing a climbing cleat to said second panel.

20. The method for providing a photovoltaic array according to claim 14, further comprising the step of providing a removable slip-in climbing cleat adapted to be supported in an opening in said second panel.
